(19) United States
(12) Patent Application Publication
(10) Pub. No.: US 2010/0180866 A1
(43) Pub. Date: Jul. 22, 2010

(54) SYSTEM AND METHOD FOR DEFINING PIEZOELECTRIC ACTUATOR WAVEFORM

(76) Inventor: RICHARD A. BECKER, Camarillo, CA (US)

Correspondence Address: SHEPPARD, MULLIN, RICHTER & HAMPTON LLP, 333 SOUTH HOPE STREET, 48TH FLOOR, LOS ANGELES, CA, 90071-1448, US

(21) Appl. No.: 12/652,674

(22) Filed: Jan. 5, 2010

Related U.S. Application Data
(60) Provisional application No. 61/144,270, filed on Jan. 13, 2009.

(51) Int. Cl. F02M 51/00; H01L 41/09

(52) U.S. Cl. 123/472; 318/116

(57) ABSTRACT

A system and method for defining a signal for driving a piezoelectric actuator, comprising defining a wave profile corresponding to a voltage waveform of a signal for actuating a piezoelectric actuator; modifying the wave profile such that an operational profile of the piezoelectric actuator is adjusted; and providing the signal to the piezoelectric actuator to operate the piezoelectric actuator.

### CROSS-REFERENCE TO RELATED APPLICATIONS

This application claims priority from U.S. Provisional Patent Application Ser. Nos. 61/144,270 filed Jan. 13, 2009, which is hereby incorporated herein by reference in its entirety.

### TECHNICAL FIELD

The present invention relates to piezoelectric devices, and more particularly, some embodiments relate to piezoelectric actuators.

### DESCRIPTION OF THE RELATED ART

Piezoelectric actuators comprise a piezoelectric element such as a piezoelectric material (e.g., a crystal, ceramic, or polymer) coupled to electrical contacts to allow a voltage to be applied to the piezoelectric material. Piezoelectric actuators utilize the converse piezoelectric effect to create a mechanical displacement in response to an applied voltage. Such actuators may be used in applications such as machine tools, disk drives, military applications, ink delivery systems for printers, medical devices, precision manufacturing, fuel injection, or any application which requires high precision or high speed fluid delivery.

In most actuators, a single piezoelectric element is used to mechanically actuate the device. While a single-element piezoelectric actuator can precisely control the total actuator displacement, the actual displacement path followed to reach the total displacement is difficult to control. When a driving voltage is applied to a single piezoelectric element, the displacement response is often not linear with respect to the applied voltage. For example, the physical effects of static or dynamic friction, or the nature of the piezoelectric material itself may prevent the actuator from responding linearly according to an applied voltage.

### BRIEF SUMMARY OF EMBODIMENTS OF THE INVENTION

According to various embodiments of the invention, a method for defining a driving signal for a piezoelectric actuator is presented that increases the ability to optimize the displacement response of a piezoelectric actuator.

One embodiment of the invention features a method for defining a signal for driving a piezoelectric actuator, comprising defining a wave profile corresponding to a voltage waveform of a signal for actuating a piezoelectric actuator; modifying the wave profile such that an operational profile of the piezoelectric actuator is adjusted; and providing the signal to the piezoelectric actuator to operate the piezoelectric actuator.

According to some embodiments of the invention, the method further comprises receiving data of effects of the signal, wherein modifying the wave profile further comprises modifying the wave profile based on the data.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

Some of the figures included herein illustrate various embodiments of the invention from different viewing angles. Although the accompanying descriptive text may refer to such views as “top,” “bottom” or “side” views, such references are merely descriptive and do not imply or require that the invention be implemented or used in a particular spatial orientation unless explicitly stated otherwise.

FIG. 1 illustrates an example of embodiment of a piezoelectric actuator having a plurality of piezoelectric elements according to an embodiment of the invention.

FIG. 2a illustrates example voltage waveform profiles according to an embodiment of the invention.

FIG. 2b illustrates example actuator displacement profiles according to an embodiment of the invention.

FIG. 3 illustrates a tool used to modify a voltage waveform according to an embodiment of the invention.

FIG. 4 is a block diagram illustrating a system and method used to determine a voltage profile to produce a desired displacement profile in the environment of an engine system, according to an embodiment of the invention.

FIG. 5 illustrates an exemplary computing module, which may be used to implement various components in particular embodiments of the invention.

The figures are not intended to be exhaustive or to limit the invention to the precise form disclosed. It should be understood that the invention can be practiced with modification and alteration, and that the invention be limited only by the claims and the equivalents thereof.

### DETAILED DESCRIPTION OF THE EMBODIMENTS OF THE INVENTION

Before describing the invention in detail, it is useful to describe an example environment with which the invention can be implemented. One such environment comprises a system requiring high speed or high precision fluid delivery.

Another such environment is a piezoelectric actuator driver of the type described in U.S. patent application Ser. No. 12/686,247, U.S. patent application Ser. No. 12/652,679, or U.S. patent application Ser. No. 12/686,298, each of which is herein incorporated by reference in its entirety. Further environments may employ piezoelectric actuator drivers of these types and a fault recovery system of the type described in U.S. patent application Ser. No. 12/652,681.

Another environment is a fuel injector for fuel delivery to a combustion chamber of an engine. For example, the fuel injector may be employed for dispensing fuel into a combustion chamber of an internal combustion engine, wherein fuel temperature and pressure are high enough that the fuel charge operates as a super-critical fluid. An example of this type of fuel injector is disclosed in U.S. Pat. No. 7,444,230, herein incorporated by reference in its entirety.

Another example is a piezoelectrically actuated fuel injector, for example, of the type disclosed in U.S. Provisional Patent Application No. 61/081,326, having a piezo actuated injector pin having a heated portion and a catalytic portion; and a temperature compensating unit; wherein fuel is dispensed into a combustion chamber of an internal combustion engine.

From time-to-time, the present invention is described herein in terms of these example environments. Description in terms of these environments is provided to allow the various features and embodiments of the invention to be portrayed in the context of an exemplary application. After reading this description, it will become apparent to one of ordinary skill in the art how the invention can be implemented in different and alternative environments.

Unless defined otherwise, all technical and scientific terms used herein have the same meaning as is commonly understood by one of ordinary skill in the art to which this invention belongs. All patents, applications, published applications and other publications referred to herein are incorporated by reference in their entirety. If a definition set forth in this section is contrary to or otherwise inconsistent with a definition set forth in applications, published applications and other publications that are herein incorporated by reference, the definition set forth in this section prevails over the definition that is incorporated herein by reference.

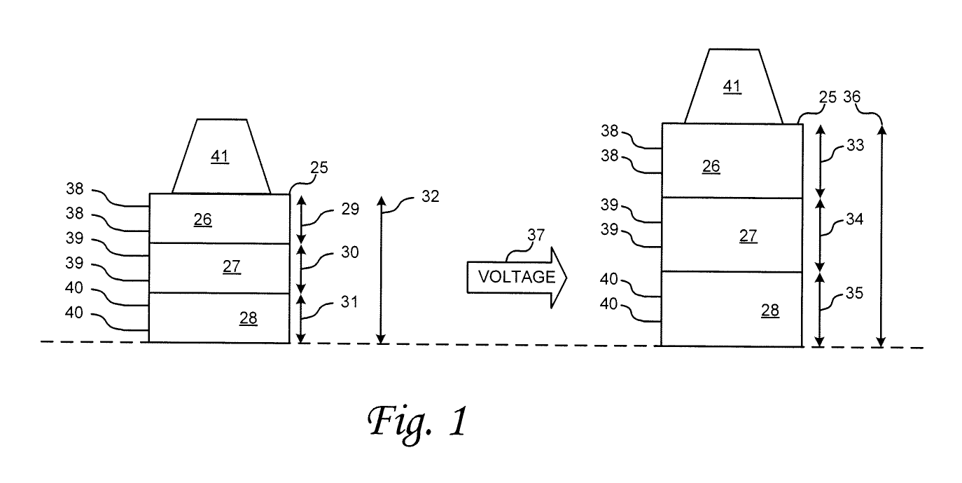

FIG. 1 illustrates a piezoelectric actuator having a plurality of piezoelectric elements according to an embodiment of the invention. Multi-element piezoelectric actuator 25 has a plurality of piezoelectric elements 26, 27, 28 connected in series. Each piezoelectric element has a corresponding rest displacement 29, 30, and 31, resulting in a total rest displacement 32. Piezoelectric elements 26, 27, and 28 may comprise a piezoelectric material, such as a piezoelectric crystal or a piezoelectric ceramic. Piezoelectric elements 26, 27, and 28 further comprise electrical contacts 38, 39, and 40, respectively. When a voltage 37 is applied to the electrical contacts, the individual piezoelectric elements expand to displacements 33, 34, and 35, respectfully, resulting in an excited displacement 36 that is greater than the rest displacement 32. Some embodiments may be configured to allow the piezoelectric elements to be operated independently of one another. For example, a voltage could be applied only to contacts 38, causing only piezoelectric element 26 to expand. In further embodiments, the voltage applied to the contacts varies as a function of time, causing the actuator displacement to also vary as a function of time. For example, (a) first, a voltage could be applied to contacts 38, causing the piezoelectric element 26 closest to the object 41 being displaced to expand to a maximum displacement; (b) second, a voltage could be applied to contacts 39, causing the piezoelectric element 27 next closest to the object 41 to expand to a maximum displacement; and (c) third, a voltage could be applied to contacts 40 causing piezoelectric element 28 farthest from the object 41 to expand to a maximum displacement. In further embodiments, the first, second, and third voltages are not applied until after the preceding piezoelectric element has reached its maximum displacement. In some embodiments, the maximum displacement may be a predetermined percentage of the total desired actuator displacement, for example, each element of a four-element actuator might have a maximum displacement of 25% of the total desired actuator displacement. In other embodiments, the maximum displacement may be physical maximum possible for each element preceding the last element to displace, and the remaining displacement distance for the last element. For example, in a three-element actuator, the desired total displacement may be 0.004 inches, and each element may be able to displace 0.0015 inches. Accordingly, the first two elements to actuate would actuate to their maximum lengths of 0.0015 inches, while the third element to actuate would actuate the remaining 0.001 inches. In this example, if the desired total displacement were only 0.003 inches, then only the first two elements would actuate.

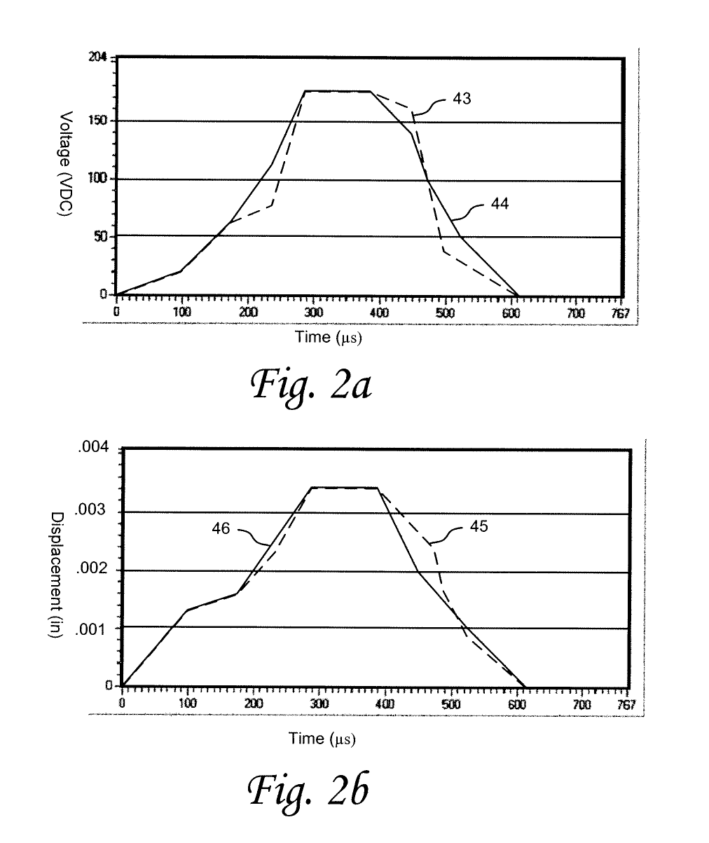

FIGS. 2a and 2b illustrate example voltage profiles and example resultant actuator displacement profiles, respectively. The graphs of FIGS. 2a and 2b are used for illustrative purposes only. A first voltage profile 44 is a voltage function of time, for example a voltage waveform. The voltage profile 44 is provided to a waveform generator to generate a voltage waveform used to actuate a piezoelectric actuator. The piezoelectric actuator actuates in time in response to the provided voltage waveform, resulting in a displacement profile 46. As illustrated, the displacement of the piezoelectric actuator may not be a linear function of the voltage applied to the driver. For example, mechanical and electrical properties of the system may prevent the displacement profile from being a linear transformation of the voltage profile. Such mechanical and electrical properties may include static and dynamic friction, fluid effects on the system, non-linear voltage response of the piezoelectric elements, and non-linear amplifier performance.

The piezoelectric actuator may have a desired displacement profile 45. For example, a fuel injector may have a desired actuator displacement profile 45 to meter fuel in a desired manner at a specific point in a dynamic operating range of an engine. The non-linearity between the voltage waveform used to drive the actuator and actuator displacement may impede predicting the voltage profile 43 required to produce the desired displacement profile 45. In the illustrated example, the change from the first voltage profile 44 to the desired voltage profile 43 produces a non-linear change in the displacement profile from the first displacement profile 46 to the desired displacement profile 45. Because the displacement profile resulting from a given voltage profile may be difficult or impossible to predict, a voltage profile may be modified until it produces a desired displacement profile.

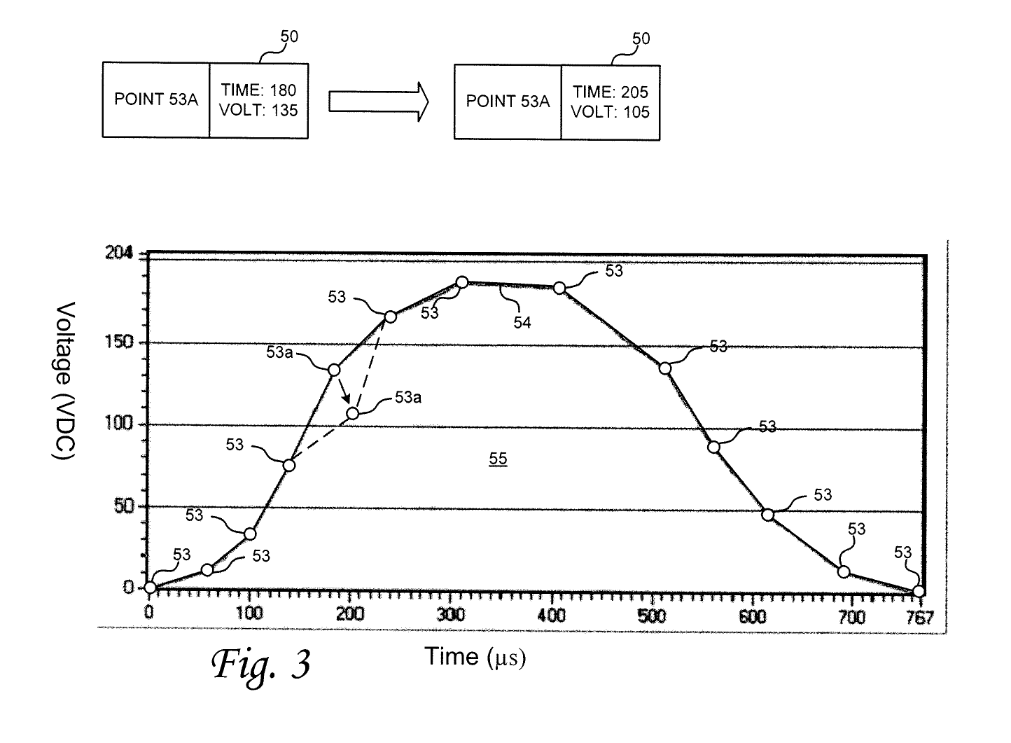

FIG. 3 illustrates a tool used to modify a voltage waveform according to an embodiment of the invention. A display window 55 may display a voltage profile 54 generated by a plurality of generating points 53. The voltage profile 54 may be modified by changing the generating points 53. For example, generating points may be repositioned, new generating points may be added, or generating points may be deleted. In the illustrated example, generating point 53a is repositioned using input tool 50. Input tool 50 displays the time and voltage of generating point 53a and is configured to allow a user to change the values of the time and voltage. In the illustrated example, point 53a is repositioned from (180 μs, 135 V) to (205 μs, 105 V). In further embodiments, the tool may be further configured to allow the user to reposition the generating points using an input cursor. For example, by selecting a generating point using a mouse cursor and dragging the point to the new position.

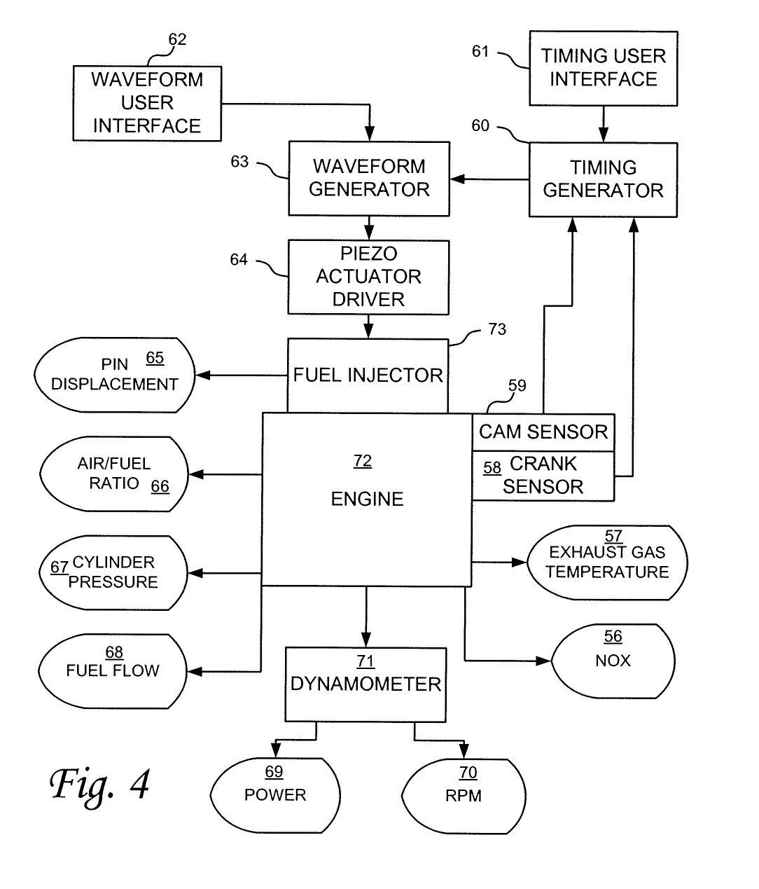

FIG. 4 is a block diagram illustrating a system and method used to determine a voltage profile to produce a desired displacement profile in the environment of an engine system, according to an embodiment of the invention. A waveform user interface 62 is used to define a voltage waveform for use in a piezoelectrically actuated fuel injector. The defined waveform is provided to a waveform generator 63, which generates the waveform and provides it a piezoelectric actuator driver 62 at intervals timed to meter fuel into an engine according to a timing trigger signal provided by a timing generator 60. The piezoelectric actuator driver 64 drives a piezoelectric actuator in the fuel injector 73 to meter an amount of fuel into the engine 72 by actuating a pin in the fuel injector. The fuel injector 73 meters an amount of fuel into a combustion chamber of a running engine 72. Data from a cam sensor 59 and crank sensor 58 are used by the timing generator 60 to generate a timing trigger signal for the waveform generator 63. This timing trigger signal 61 may be modified or adjusted using a timing user interface tool 61.

A sensor measures the pin displacement and displays the pin displacement profile on a pin displacement display 65. The user may modify the voltage waveform using the waveform user interface 62 based on the pin displacement profile. For example, the user may iteratively modify the voltage waveform until the pin displacement profile approximates a desired displacement profile within a predetermined tolerance, e.g., until the displacement profile is within 0.0001″ of a desired displacement profile at the greatest deviation. The engine is also coupled to sensors and display which provide, for example, (a) the air/fuel ratio 66, (b) the cylinder pressure, (c) the fuel flow, (d) the exhaust gas temperature, (e) and NOx levels. The engine is further coupled to a dynamometer 71 that has sensors that output to an engine power display 69 and an engine RPM display 70. These displays allow the user to view the secondary effects of changes to the voltage waveform. For example, the fuel flow rate, the NOx levels, the cylinder pressure profile, or the exhaust gas temperature may be effected by changes to how the actuator displaces. Each display may be configured to display real-time data on the running engine. The waveform user interface tool 62 may also be configured to change and provide a defined waveform to the waveform generator in real-time. Accordingly, the system allows a user to view, in real-time, the effects of a modification to the waveform. The use may view the effects waveform modifications on the actuator displacement profile as well as the secondary effects on, for example, fuel delivery profile, combustion heat release profile, cylinder temperature, and pressure profile.

In further embodiments, a plurality of waveforms may be defined, such that each waveform produces a particular displacement profile at a specific point on a table covering the dynamic operating range for the engine. For example, the system described herein may be operated at hundreds of different points of the dynamic operating range of the engine. For each point, a waveform may be produced that provides a displacement profile that optimizes the combustion process at that operating point.

In other embodiments, the piezoelectric actuator driver may be a multi-element piezoelectric driver. In such an embodiment, the multi-element piezoelectric actuator may have a plurality of channels, each channel providing a signal to a separate piezoelectric element, wherein the signals correspond to multiple instances of the voltage waveform that are amplified at different predetermined amplification voltages and offset and clipped at different predetermined clipping voltages. In these embodiments, the waveform user interface tool 62 may be further configured to allow modification of the predetermined amplifications voltages and predetermined clipping voltages. For example, if a voltage waveform requires all three elements of a three-element piezoelectric actuator, the waveform user interface 62 may be used to modify the predetermined amplification times. For example, at a particular operating point it may be desirable to amplify the 1st channel at 20% of the waveform maximum voltage; the 2nd channel at 50% of the waveform maximum voltage; and the third channel at the maximum waveform voltage. At another operating point it may be desirable to amplify the 1st channel at ⅓ the maximum waveform voltage; the 2nd channel at ⅔ the maximum waveform voltage; and the 3rd channel at the maximum waveform voltage.

In further embodiments, the waveform user interface 62 may be used to define a plurality of alternative waveforms that may be used by the fuel injector to provide a fault recovery mode, for example, in a multi-element fuel injector employing a fault recovery system. A plurality of alternative waveform may be defined that can be routed to the remaining functional elements of the multi-element piezoelectric actuator, if one of the piezoelectric elements fails.

The term tool can be used to refer to any apparatus configured to perform a recited function. For example, tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance on which software runs or in which hardware is implemented.

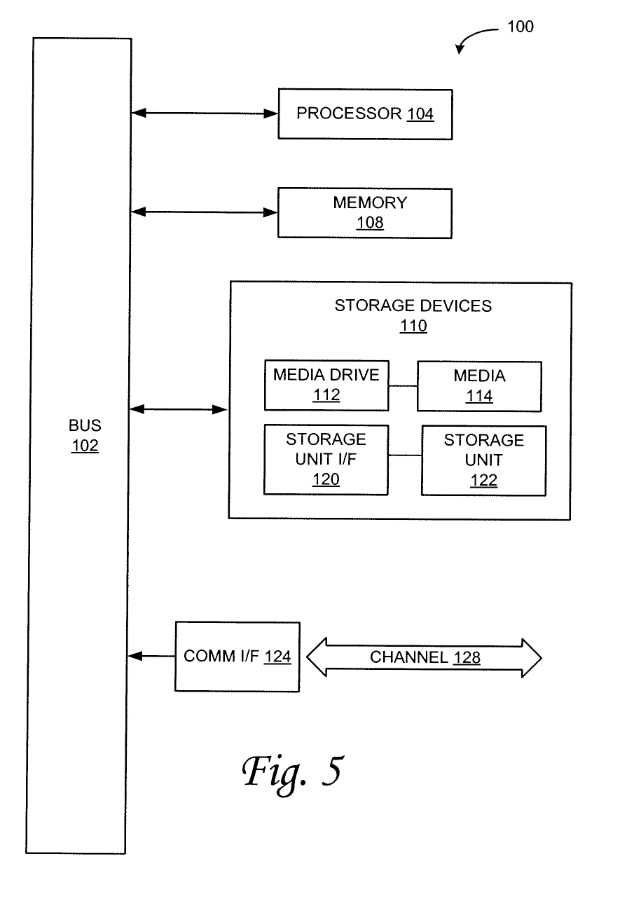

As used herein, the term module might describe a given unit of functionality that can be performed in accordance with one or more embodiments of the present invention. As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

Where components or modules of the invention are implemented in whole or in part using software, in one embodiment, these software elements can be implemented to operate with a computing or processing module capable of carrying out the functionality described with respect thereto. One such example-computing module is shown in FIG. 5. Various embodiments are described in terms of this example-computing module 100. After reading this description, it will become apparent to a person skilled in the relevant art how to implement the invention using other computing modules or architectures.

Referring now to FIG. 5, computing module 100 may represent, for example, computing or processing capabilities found within desktop, laptop and notebook computers; hand-held computing devices (PDA's, smart phones, cell phones, palmtops, etc.); mainframes, supercomputers, workstations or servers; or any other type of special-purpose or general-purpose computing devices as may be desirable or appropriate for a given application or environment. Computing module 100 might also represent computing capabilities embedded within or otherwise available to a given device. For example, a computing module might be found in other electronic devices such as, for example, digital cameras, navigation systems, cellular telephones, portable computing devices, modems, routers, WAPs, terminals and other electronic devices that might include some form of processing capability.

Computing module 100 might include, for example, one or more processors, controllers, control modules, or other processing devices, such as a processor 104. Processor 104 might be implemented using a general-purpose or special-purpose processing engine such as, for example, a microprocessor, controller, or other control logic. In the example illustrated in FIG. 5, processor 104 is connected to a bus 102, although any communication medium can be used to facilitate interaction with other components of computing module 100 or to communicate externally.

Computing module 100 might also include one or more memory modules, simply referred to herein as main memory 108. For example, preferably random access memory (RAM) or other dynamic memory, might be used for storing information and instructions to be executed by processor 104. Main memory 108 might also be used for storing temporary variables or other intermediate information during execution of instructions to be executed by processor 104. Computing module 100 might likewise include a read only memory (“ROM”) or other static storage device coupled to bus 102 for storing static information and instructions for processor 104.

The computing module 100 might also include one or more various forms of information storage mechanism 110, which might include, for example, a media drive 112 and a storage unit interface 120. The media drive 112 might include a drive or other mechanism to support fixed or removable storage media 114. For example, a hard disk drive, a floppy disk drive, a magnetic tape drive, an optical disk drive, a CD or DVD drive (R or RW), or other removable or fixed media drive might be provided. Accordingly, storage media 114, might include, for example, a hard disk, a floppy disk, magnetic tape, cartridge, optical disk, a CD or DVD, or other fixed or removable medium that is read by, written to or accessed by media drive 112. As these examples illustrate, the storage media 114 can include a computer usable storage medium having stored therein computer software or data.

In alternative embodiments, information storage mechanism 110 might include other similar instrumentalities for allowing computer programs or other instructions or data to be loaded into computing module 100. Such instrumentalities might include, for example, a fixed or removable storage unit 122 and an interface 120. Examples of such storage units 122 and interfaces 120 can include a program cartridge and cartridge interface, a removable memory (for example, a flash memory or other removable memory module) and memory slot, a PCMCIA slot and card, and other fixed or removable storage units 122 and interfaces 120 that allow software and data to be transferred from the storage unit 122 to computing module 100.

Computing module 100 might also include a communications interface 124. Communications interface 124 might be used to allow software and data to be transferred between computing module 100 and external devices. Examples of communications interface 124 might include a modem or softmodem, a network interface (such as an Ethernet, network interface card, WiMedia, IEEE 802.XX or other interface), a communications port (such as for example, a USB port, IR port, RS212 port Bluetooth® interface, or other port), or other communications interface. Software and data transferred via communications interface 124 might typically be carried on signals, which can be electronic, electromagnetic (which includes optical) or other signals capable of being exchanged by a given communications interface 124. These signals might be provided to communications interface 124 via a channel 128. This channel 128 might carry signals and might be implemented using a wired or wireless communication medium. These signals can deliver the software and data from memory or other storage medium in one computing system to memory or other storage medium in computing system 100. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to physical storage media such as, for example, memory 108, storage unit 120, and media 114. These and other various forms of computer program media or computer usable media may be involved in storing one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing module 100 to perform features or functions of the present invention as discussed herein.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

1. A method for defining a signal for driving a piezoelectric actuator, comprising:
defining a wave profile corresponding to a voltage waveform of a signal for actuating a piezoelectric actuator;
modifying the wave profile such that an operational profile of the piezoelectric actuator is adjusted; and
providing the signal to the piezoelectric actuator to operate the piezoelectric actuator.

2. The method of claim 1, further comprising:
receiving data of effects of the signal;
wherein modifying the wave profile further comprises modifying the wave profile based on the data.

3. The method of claim 2, further comprising repeating the steps of modifying the wave profile, providing the signal, and receiving the data.

4. The method of claim 3, wherein the steps of modifying, providing, and receiving are repeated until the operational profile approximates a desired operational profile within a predetermined tolerance.

5. The method of claim 1, wherein the operational profile of the piezoelectric actuator is a displacement profile.

6. The method of claim 2, wherein the data comprises a displacement profile of the piezoelectric actuator.

7. The method of claim 6, wherein the data further comprises effects of the displacement profile on a system comprising the piezoelectric actuator.

8. The method of claim 7, wherein the system further comprises a fuel injector that is operated using the piezoelectric actuator.

9. The method of claim 8, wherein the fuel injector is employed for fuel delivery to a combustion chamber of an engine.

10. A system for defining a signal for driving a piezoelectric actuator, comprising:
means for defining a wave profile corresponding to a voltage waveform of a signal for actuating a piezoelectric actuator;
means for modifying the wave profile such that an operational profile of the piezoelectric actuator is adjusted; and
means for providing the signal to the piezoelectric actuator to operate the piezoelectric actuator.

11. The system of claim 10, further comprising:
means for receiving data of effects of the signal;
wherein means for modifying the wave profile further comprises means for modifying the wave profile based on the data.

12. The system of claim 2, further comprising means for repeating modifying the wave profile, providing the signal, and receiving the data.

13. The system of claim 3, wherein modifying, providing, and receiving are repeated until the operational profile approximates a desired operational profile within a predetermined tolerance.

14. The system of claim 1, wherein the operational profile of the piezoelectric actuator is a displacement profile.

15. The system of claim 2, wherein the data comprises a displacement profile of the piezoelectric actuator.

16. The system of claim 6, wherein the data further comprises effects of the displacement profile on a subsystem comprising the piezoelectric actuator.

17. The system of claim 7, wherein the subsystem further comprises a fuel injector that is operated using the piezoelectric actuator.

18. The system of claim 8, wherein the fuel injector is employed for fuel delivery to a combustion chamber of an engine.
